(19) United States
(12) Patent Application Publication
(10) Pub. No.: US 2026/0155170 A1
(43) Pub. Date: Jun. 4, 2026

(54) Data receiving apparatus and method having data valid window expanding mechanism

(71) Applicant: REALTEK SEMICONDUCTOR CORPORATION, Hsinchu (TW)

(72) Inventors: Shih-Chang CHEN, Hsinchu (TW); Chun-Chi YU, Hsinchu (TW); Chih-Wei Chang, Hsinchu (TW)

(21) Appl. No.: 19/404,344

(22) Filed: Dec. 1, 2025

(30) Foreign Application Priority Data
Dec. 3, 2024 (TW) 113146876

(51) Int. Cl. G11C 11/4096

(52) U.S. Cl. CPC G11C 11/4096

(57) ABSTRACT

A data receiving apparatus having a data valid window expanding mechanism is provided. A data pre-processing circuit performs AND and OR logic operations on an input data signal and a delayed data signal to generate an AND gate processed signal and an OR gate processed signal. A sampling circuit performs sampling according to a sampling rising edge and a sampling falling edge of a data strobe signal to generate AND gate rising and falling edge sampling results and OR gate rising and falling edge sampling results such that a rising edge selection circuits and a falling edge selection circuit determine a current rising edge sampling result and a current falling edge sampling result to control a rising edge data multiplexer and a falling edge data multiplexer to output current rising edge data and current falling edge data accordingly.

### BACKGROUND OF THE INVENTION

### 1. Field of the Invention

The present invention relates to a data receiving apparatus and a data receiving method having a data valid window expanding mechanism.

### 2. Description of Related Art

A double data rate (DDR) memory can perform data transmission according to a rising edge and a falling edge of a system clock signal to accomplish a transmission speed that is twice the system clock signal. In conventional designs, the data receiving apparatus in the DDR memory uses a plurality of clock signals to perform over-sampling and dynamically adjusts the sampling timing according to the relation of a plurality of sampling results to guarantee the accuracy of the sampling.

However, due to the faster speed of the memory, the condition of channel dispersion becomes severe. Under the condition that only the over-sampling mechanism is used to perform data sampling, the degree of the signal transition in some data sequences may not be enough such that the over-sampling mechanism may sample false results. The sampling timing cannot be adjusted accurately such that an error may occur in the final sampling result.

### SUMMARY OF THE INVENTION

In consideration of the problem of the prior art, an object of the present invention is to supply a data receiving apparatus and a data receiving method having a data valid window expanding mechanism

The present invention discloses a data receiving apparatus having a data valid window expanding mechanism that includes a data pre-processing circuit, a sampling circuit, a data phase state storage circuit, a rising edge data multiplexer, a falling edge data multiplexer, a rising edge selection circuit and a falling edge selection circuit. The data pre-processing circuit performs an AND logic operation and an OR logic operation on an input data signal and a delayed data signal generated by delaying the input data signal to generate an AND gate processed signal and an OR gate processed signal. The sampling circuit performs sampling on the AND gate processed signal and the OR gate processed signal according to a sampling rising edge and a sampling falling edge of a data strobe signal corresponding to a data middle timing to generate an AND gate rising edge sampling result, an OR gate rising edge sampling result, an AND gate falling edge sampling result and an OR gate falling edge sampling result. The data phase state storage circuit stores a rising edge phase state and a falling edge phase state. The rising edge selection circuit determines a current rising edge sampling result according to a previous falling edge sampling result, the AND gate rising edge sampling result, the OR gate rising edge sampling result and the rising edge phase state, so as to control a rising edge data multiplexer to select the OR gate rising edge sampling result to be outputted as a current rising edge data when the current rising edge sampling result is a high state, and to control the rising edge data multiplexer to select the AND gate rising edge sampling result to be outputted as the current rising edge data when the current rising edge sampling result is a low state, wherein the previous falling edge sampling result is neighboring to the current rising edge sampling result. The falling edge selection circuit determines a current falling edge sampling result according to the previous rising edge sampling result, the AND gate falling edge sampling result, the OR gate falling edge sampling result and the falling edge phase state, so as to control a falling edge data multiplexer to select the OR gate falling edge sampling result to be outputted as a current falling edge data when the current falling edge sampling result is the high state, and to control the falling edge data multiplexer to select the AND gate falling edge sampling result to be outputted as the current falling edge data when the current falling edge sampling result is the low state, wherein the previous rising edge sampling result is neighboring to the current falling edge sampling result.

The present invention also discloses a data receiving method having a data valid window expanding mechanism that includes steps outlined below. An AND logic operation and an OR logic operation are performed on an input data signal and a delayed data signal generated by delaying the input data signal to generate an AND gate processed signal and an OR gate processed signal by a data pre-processing circuit. Sampling is performed on the AND gate processed signal and the OR gate processed signal by a sampling circuit according to a sampling rising edge and a sampling falling edge of a data strobe signal corresponding to a data middle timing to generate an AND gate rising edge sampling result, an OR gate rising edge sampling result, an AND gate falling edge sampling result and an OR gate falling edge sampling result. A current rising edge sampling result is determined by a rising edge selection circuit according to a previous falling edge sampling result, the AND gate rising edge sampling result, the OR gate rising edge sampling result and a rising edge phase state stored by a data phase state storage circuit, so as to control a rising edge data multiplexer to select the OR gate rising edge sampling result to be outputted as a current rising edge data when the current rising edge sampling result is a high state, and to control the rising edge data multiplexer to select the AND gate rising edge sampling result to be outputted as the current rising edge data when the current rising edge sampling result is a low state, wherein the previous falling edge sampling result is neighboring to the current rising edge sampling result. A current falling edge sampling result is determined by a falling edge selection circuit according to the previous rising edge sampling result, the AND gate falling edge sampling result, the OR gate falling edge sampling result and a falling edge phase state stored by the data phase state storage circuit, so as to control a falling edge data multiplexer to select the OR gate falling edge sampling result to be outputted as a current falling edge data when the current falling edge sampling result is the high state, and to control the falling edge data multiplexer to select the AND gate falling edge sampling result to be outputted as the current falling edge data when the current falling edge sampling result is the low state, wherein the previous rising edge sampling result is neighboring to the current falling edge sampling result.

These and other objectives of the present invention will no doubt become obvious to those of ordinary skill in the art behind reading the following detailed description of the preferred embodiments that are illustrated in the various figures and drawings.

### BRIEF DESCRIPTION OF THE DRAWINGS

FIG. 1 illustrates a block diagram of a data receiving apparatus according to an embodiment of the present invention.

FIG. 2 illustrates a waveform diagram of a plurality of signals related to the operation of the data receiving apparatus according to an embodiment of the present invention.

FIG. 3 illustrates a more detailed block diagram of the data pre-processing circuit according to an embodiment of the present invention.

FIG. 4 illustrates a more detailed block diagram of the sampling circuit according to an embodiment of the present invention.

FIG. 5A and FIG. 5B illustrate diagrams of data sequences according to an embodiment of the present invention.

FIG. 6 illustrates a table of the signal combinations for the rising edge selection circuit to perform selection according to an embodiment of the present invention.

FIG. 7 illustrates a table of the signal combinations for the rising edge selection circuit to perform selection according to an embodiment of the present invention.

FIG. 8 illustrates a flow chart of a data receiving method having a data valid window expanding mechanism according to an embodiment of the present invention.

### DETAILED DESCRIPTION OF THE PREFERRED EMBODIMENTS

An aspect of the present invention is to provide a data receiving apparatus and a data receiving method having a data valid window expanding mechanism to perform an AND logic operation and an OR logic operation on an input data signal and a delayed data signal to generate an AND gate processed signal and an OR gate processed signal and perform sampling thereon. Further, according to previous sampling results and current sampling results, one of the AND gate sampling result and the OR gate sampling result having a larger secured margin is selected to be a current sampled data to accomplish the data valid window expanding mechanism. The accuracy of the data sampling is improved.

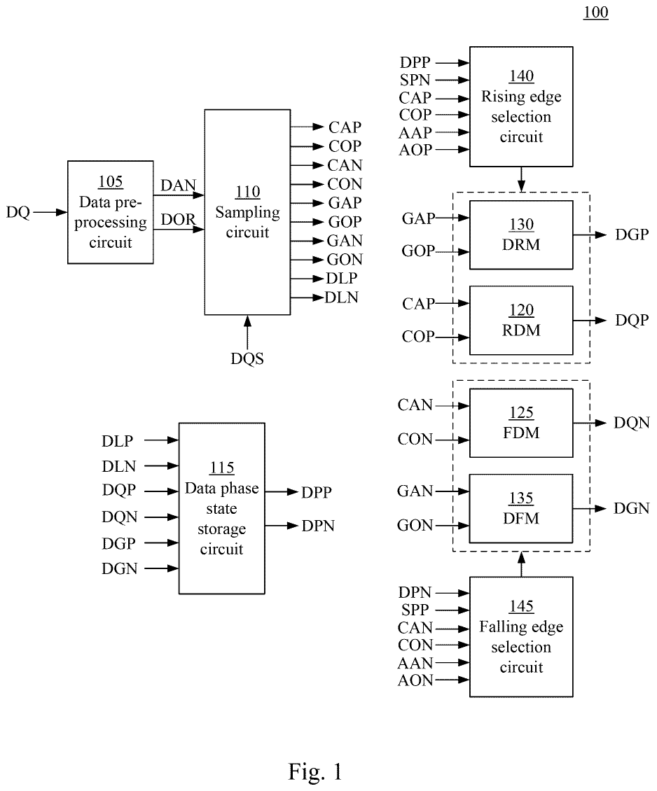

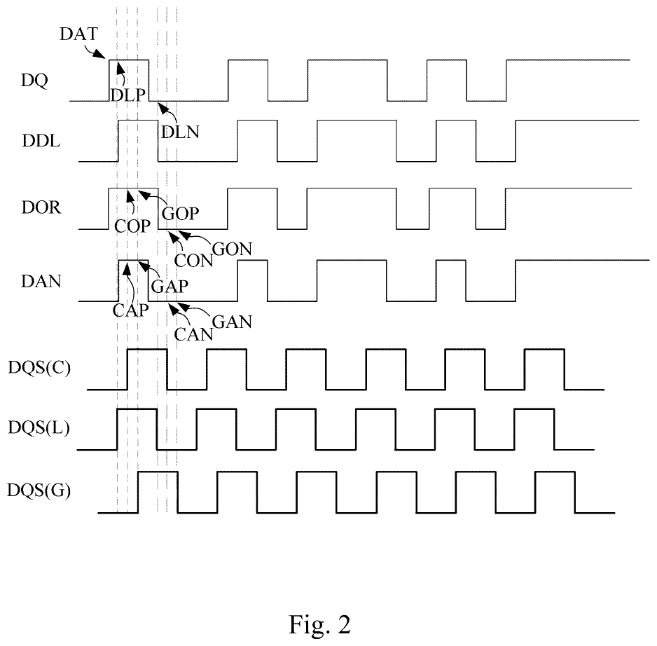

Reference is now made to FIG. 1. FIG. 1 illustrates a block diagram of a data receiving apparatus 100 according to an embodiment of the present invention. FIG. 2 illustrates a waveform diagram of a plurality of signals related to the operation of the data receiving apparatus 100 according to an embodiment of the present invention. In FIG. 2, the X-axis stands for time and the Y-axis stands for signal intensity.

The data receiving apparatus 100 can be disposed in such as, but not limited to a double data rate (DDR) memory and includes a data pre-processing circuit 105, a sampling circuit 110, a data phase state storage circuit 115, a rising edge data multiplexer 120 (abbreviated as RDM in FIG. 1), a falling edge data multiplexer 125 (abbreviated as FDM in FIG. 1), a data rear section rising edge data multiplexer 130 (abbreviated as DRM in FIG. 1), a data rear section falling edge data multiplexer 135 (abbreviated as DFM in FIG. 1), a rising edge selection circuit 140 and a falling edge selection circuit 145.

The data pre-processing circuit 105 performs an AND logic operation and an OR logic operation on an input data signal DQ and the delayed data signal DDL generated by delaying the input data signal DQ to generate an AND gate processed signal DAN and an OR gate processed signal DOR.

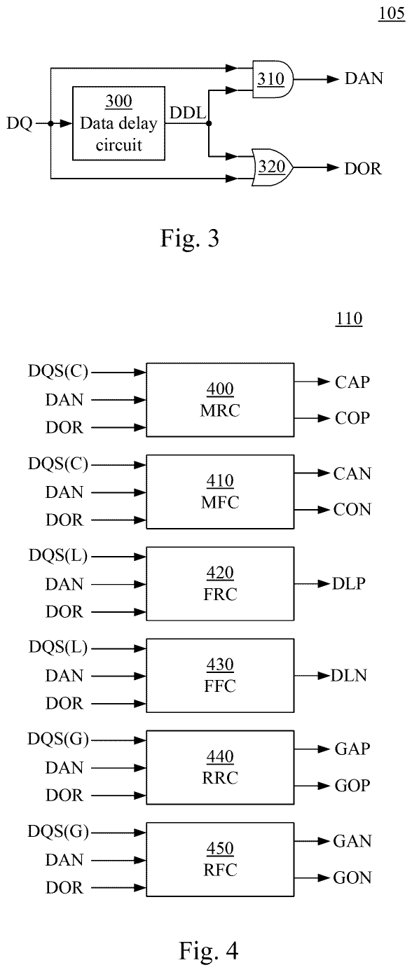

Reference is now made to FIG. 3 at the same time. FIG. 3 illustrates a more detailed block diagram of the data pre-processing circuit 105 according to an embodiment of the present invention. As illustrated in FIG. 3, the data pre-processing circuit 105 includes a data delay circuit 300, an AND gate 310 and an OR gate 320.

The data delay circuit 300 receives and delays the input data signal DQ to generate the delayed data signal DDL. The AND gate 310 performs the AND logic operation on the input data signal DQ and the delayed data signal DDL to generate the AND gate processed signal DAN. The OR gate 320 performs the OR logic operation on the input data signal DQ and the delayed data signal DDL to generate the OR gate processed signal DOR.

As illustrated in FIG. 2, when any one of the input data signal DQ and the delayed data signal DDL is at the low state, the AND gate processed signal DAN is at the low state. Only when each of the input data signal DQ and the delayed data signal DDL is at the high state, the AND gate processed signal DAN is at the high state. On the other hand, when any one of the input data signal DQ and the delayed data signal DDL is at the high state, the OR gate processed signal DOR is at the high state. Only when each of the input data signal DQ and the delayed data signal DDL is at the low state, the OR gate processed signal DOR is at the low state.

It is appreciated that since the processing of the circuit takes time, the timings of the AND gate processed signal DAN and the OR gate processed signal DOR are slightly later than the timing of the input data signal DQ. However, in order to observe the relation among different signals, the AND gate processed signal DAN and the OR gate processed signal DOR are illustrated to be aligned with the input data signal DQ in FIG. 2.

The sampling circuit 110 performs sampling on the AND gate processed signal DAN and the OR gate processed signal DOR according to a sampling rising edge and a sampling falling edge of a data strobe signal DQS corresponding to a data middle timing to generate an AND gate rising edge sampling result CAP, an OR gate rising edge sampling result COP, an AND gate falling edge sampling result CAN and an OR gate falling edge sampling result CON.

Reference is now made to FIG. 4. FIG. 4 illustrates a more detailed block diagram of the sampling circuit 110 according to an embodiment of the present invention. As illustrated in FIG. 4, the sampling circuit 110 includes a data middle section rising edge sampling circuit 400 (abbreviated as MRC), a data middle section falling edge sampling circuit 410 (abbreviated as MFC), a data front section rising edge sampling circuit 420 (abbreviated as FRC), a data front section falling edge sampling circuit 430 (abbreviated as FFC), a data rear section rising edge sampling circuit 440 (abbreviated as RRC) and a data rear section falling edge sampling circuit 450 (abbreviated as RFC).

In an embodiment, since the AND gate processed signal DAN and the OR gate processed signal DOR are generated by processing the input data signal DQ by using a plurality of circuits, the data receiving apparatus 100 may selectively include a data strobe delay circuit (not illustrated in the figure) to receive and delay an original data strobe signal (not illustrated in the figure) corresponding to the input data signal DQ to generate the data strobe signal DQS.

For the data to be sampled, a timing adjusting circuit (not illustrated in the figure) can be used to adjust the timing of the data strobe signal DQS to generate a data strobe signal DQS(C) corresponding to the data middle timing, a data strobe signal DQS(L) corresponding to a data front section timing before the data middle timing and a data strobe signal DQS(G) corresponding to a data rear section timing behind data middle timing illustrated in FIG. 2.

The data middle section rising edge sampling circuit 400, corresponding to the data middle timing, samples the AND gate processed signal DAN according to a sampling rising edge of the data strobe signal DQS(C) to generate the AND gate rising edge sampling result CAP and samples the OR gate processed signal DOR according to the sampling rising edge of the data strobe signal DQS(C) to generate the OR gate rising edge sampling result COP. For example, corresponding to a piece of data DAT in FIG. 2, the data middle section rising edge sampling circuit 400 samples the AND gate rising edge sampling result CAP that is the high state and the AND gate rising edge sampling result CAP that is the high state.

The data middle section falling edge sampling circuit 410, corresponding to the data middle timing, samples the AND gate processed signal DAN according to a sampling falling edge of the data strobe signal DQS(C) to generate the AND gate falling edge sampling result CAN and samples the OR gate processed signal DOR according to the sampling falling edge of the data strobe signal DQS(C) to generate the OR gate falling edge sampling result CON. For example, corresponding to the data DAT in FIG. 2, the data middle section falling edge sampling circuit 410 samples the AND gate falling edge sampling result CAN that is the low state and the OR gate falling edge sampling result CON that is the low state.

The data front section rising edge sampling circuit 420, corresponding to the data front section timing, samples the input data signal DQ according to a sampling rising edge of the data strobe signal DQS(L) to generate and output a data front section rising edge data DLP. For example, corresponding to the data DAT in FIG. 2, the data front section rising edge sampling circuit 420 samples the data front section rising edge data DLP that is the high state.

The data front section falling edge sampling circuit 430, corresponding to the data front section timing, samples the input data signal DQ according to a sampling falling edge of the data strobe signal DQS(L) to generate and output a data front section falling edge data DLN. For example, corresponding to the data DAT in FIG. 2, the data front section falling edge sampling circuit 430 samples the data front section falling edge data DLN that is the low state.

The data rear section rising edge sampling circuit 440, corresponding to the data rear section timing, samples the AND gate processed signal DAN according to a sampling rising edge of the data strobe signal DQS(G) to generate a data rear section AND gate rising edge sampling result GAP and samples the OR gate processed signal DOR according to the sampling rising edge of the data strobe signal DQS(G) to generate a data rear section OR gate rising edge sampling result GOP. For example, corresponding to the data DAT in FIG. 2, the data rear section rising edge sampling circuit 440 samples data rear section AND gate rising edge sampling result GAP that is the high state and the data rear section OR gate rising edge sampling result GOP that is the high state.

The data rear section falling edge sampling circuit 450, corresponding to the data rear section timing, samples the AND gate processed signal DAN according to a sampling falling edge of the data strobe signal DQS(G) to generate a data rear section AND gate falling edge sampling result GAN and samples the OR gate processed signal DOR according to the sampling falling edge of the data strobe signal DQS(G) to generate a data rear section OR gate falling edge sampling result GON. For example, corresponding to the data DAT in FIG. 2, the data middle section falling edge sampling circuit 410 samples the data rear section AND gate falling edge sampling result GAN that is the low state and the data rear section OR gate falling edge sampling result GON that is the low state.

The range of the data front section timing, the data middle timing and the data rear section timing does not exceed the time length of one piece of data to over-sample one piece of data based on the sampling mechanism described above.

Reference is now made to FIG. 1 again, the data phase state storage circuit 115 stores a rising edge phase state DPP and a falling edge phase state DPN. The state of each of the rising edge phase state DPP and the falling edge phase state DPN may indicate a “lead state” and a “lag state” based on the content included therein. The detail of the rising edge phase state DPP and falling edge phase state DP is described later.

The rising edge data multiplexer 120 receives the AND gate rising edge sampling result CAP and the OR gate rising edge sampling result COP. The falling edge data multiplexer 125 receives the AND gate falling edge sampling result CAN and the OR gate falling edge sampling result CON. The data rear section rising edge data multiplexer 130 receives the data rear section AND gate rising edge sampling result GAP and data rear section OR gate rising edge sampling result GOP. The data rear section falling edge data multiplexer 135 receives the data rear section AND gate falling edge sampling result GAN and the data rear section OR gate falling edge sampling result GON.

These multiplexers perform the selection and output of the signals according to the operation of the rising edge selection circuit 140 and the falling edge selection circuit 145.

Take the rising edge selection circuit 140 as an example, the rising edge selection circuit 140 determines a current rising edge sampling result according to a previous falling edge sampling result SPN, the AND gate rising edge sampling result CAP, the OR gate rising edge sampling result COP and the rising edge phase state DPP and controls the rising edge data multiplexer 120 and the data rear section rising edge data multiplexer 130 to perform the selection and output of the signals according to the current rising edge sampling result.

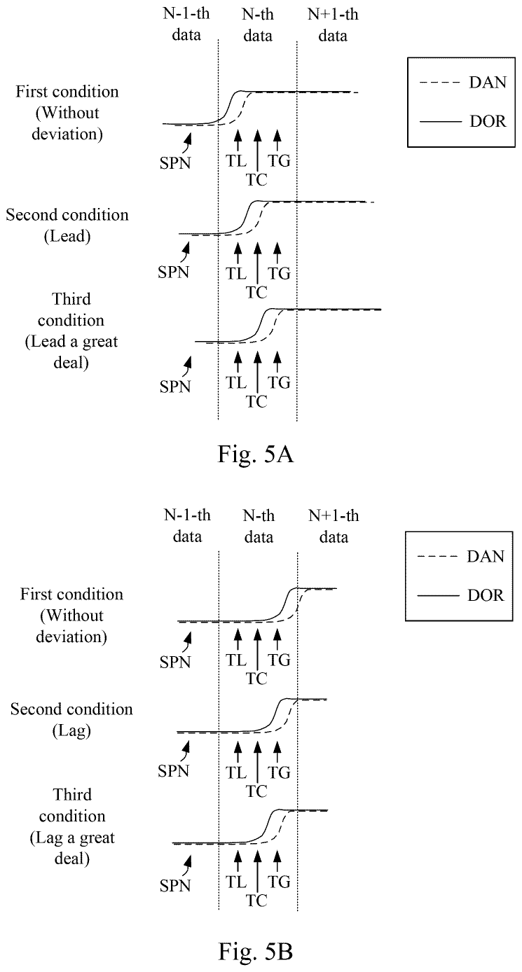

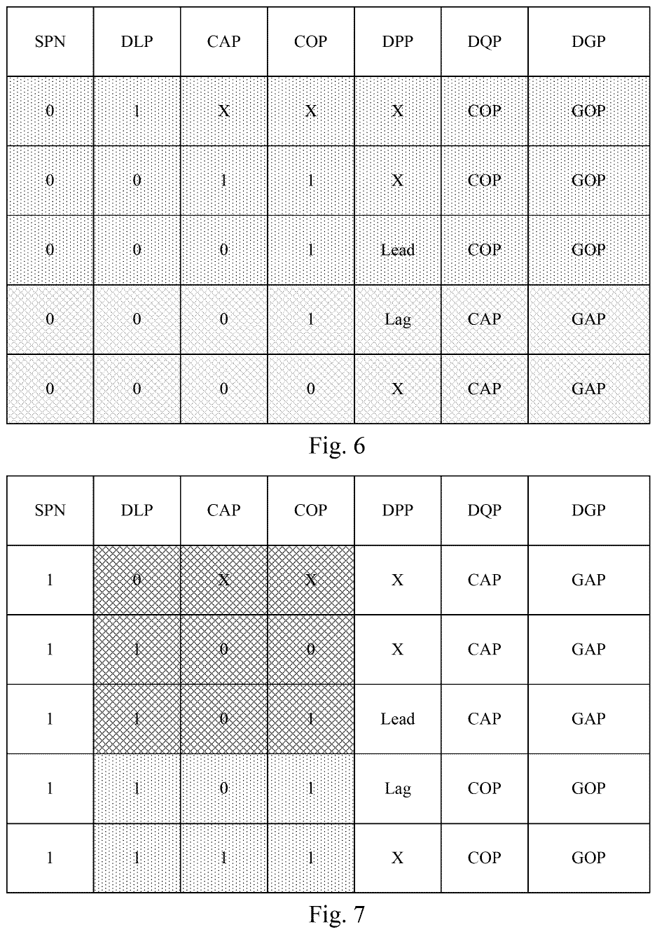

Reference is now made to FIG. 5A, FIG. 5B and FIG. 6 at the same time. FIG. 5A and FIG. 5B illustrate diagrams of data sequences according to an embodiment of the present invention. FIG. 6 illustrates a table of the signal combinations for the rising edge selection circuit 140 to perform selection according to an embodiment of the present invention.

The data sequences in FIG. 5A and FIG. 5B are the AND gate processed signal DAN and the OR gate processed signal DOR processed by the AND gate 310 and the OR gate 320 in FIG. 3, wherein the AND gate processed signal DAN is illustrated as dashed lines and the OR gate processed signal DOR is illustrated as solid lines.

FIG. 5A illustrates a data sequence (0, 1, 1) having three consecutive pieces of data including the N−1-th data, the N-th data and the N+1-th data under three different timing conditions. The N-th data that is 1 is the current data to be sampled, and the data strobe signal DQS performs sampling corresponding to a data middle timing TC, a data front section timing TL and a data rear section timing TG. The three timing conditions respectively correspond to the sampling results of the first three rows in the table in FIG. 6.

In the first condition in FIG. 5A, the data middle timing TC is roughly aligned to the center of the data without deviation. Under such a condition, as shown in the first row in FIG. 6, the rising edge selection circuit 140 directly determines that the current rising edge sampling result is the high state when the previous falling edge sampling result SPN is the low state and the data front section rising edge data DLP is the high state. The previous falling edge sampling result SPN is the sampling result generated according to the data strobe signal DQS and is neighboring and in front of the current rising edge sampling result. In the example in FIG. 6, the previous falling edge sampling result SPN is the sampling result of the N−1-th data that is 0.

In the second condition in FIG. 5A, the timing of the data is slightly leading such that the data middle timing TC is behind the center of the data. Under such a condition, as illustrated in the second row in FIG. 6, the rising edge selection circuit 140 determines that the current rising edge sampling result is the high state when the previous falling edge sampling result SPN is the low state and each of the AND gate rising edge sampling result CAP and the OR gate rising edge sampling result COP is the high state.

In the third condition in FIG. 5A, the timing of the data is leading in a greater deal such that the data middle timing TC is way behind the center of the data. Under such a condition, as illustrated in the third row in FIG. 6, the rising edge selection circuit 140 determines that the current rising edge sampling result is the high state when each of the previous falling edge sampling result SPN, the data front section rising edge data DLP and the AND gate rising edge sampling result CAP is the low state, the OR gate rising edge sampling result COP is the high state and the rising edge phase state DPP is the lead state.

The entries in the first three rows in FIG. 6 are illustrated to be filled with dotted pattern to indicate the conditions that the current rising edge sampling result is determined to be the high state. As a result, when the current rising edge sampling result is the high state, the rising edge selection circuit 140 controls the rising edge data multiplexer 120 to select the OR gate rising edge sampling result COP to be outputted as a current rising edge data DQP and controls the data rear section rising edge data multiplexer 130 to select the data rear section OR gate rising edge sampling result GOP to be outputted as a data rear section rising edge data DGP.

It is appreciated that when the data sequence is (0, 1, 0), the same mechanism described above can be used to perform selection. The detail is not described herein.

FIG. 5B illustrates a data sequence (0, 0, 1) having three consecutive pieces of data including the N−1-th data, the N-th data and the N+1-th data under three different timing conditions. The N-th data that is 0 is the current data to be sampled, and the data strobe signal DQS performs sampling corresponding to a data middle timing TC, a data front section timing TL and a data rear section timing TG. The three timing conditions respectively correspond to the sampling results of the last two rows in the table in FIG. 6.

In the first condition in FIG. 5B, the data middle timing TC is roughly aligned to the center of the data without deviation. In the second condition in FIG. 5B, the timing of the data is slightly lagging such that the data middle timing TC is ahead of the center of the data. Under such two conditions, as illustrated in the fifth row in FIG. 6, the rising edge selection circuit 140 determines that the current rising edge sampling result is the low state when the previous falling edge sampling result SPN is the low state, and each of the AND gate rising edge sampling result CAP and the OR gate rising edge sampling result COP is the low state.

In the third condition in FIG. 5B, the timing of the data is lagging in a greater deal such that the data middle timing TC is way ahead of the center of the data. Under such a condition, as illustrated in the fourth row in FIG. 6, the rising edge selection circuit 140 determines that the current rising edge sampling result is the low state when each of the previous falling edge sampling result SPN, the data front section rising edge data DLP and the AND gate rising edge sampling result CAP is the low state, the OR gate rising edge sampling result COP is the high state and the rising edge phase state DPP is the lag state.

It is appreciated that the sampling results of the third condition in FIG. 5A and the third condition in FIG. 5B (corresponding to the third row and the fourth row in FIG. 6 are quite close. As a result, the rising edge selection circuit 140 requires the aid of the rising edge phase state DPP to determine whether the data is the lead state or the lag state.

The entries in the last two rows in FIG. 6 are illustrated to be filled with mesh-like pattern to indicate the conditions that the current rising edge sampling result is determined to be the low state. As a result, the rising edge selection circuit 140 controls the rising edge data multiplexer 120 to select the AND gate rising edge sampling result CAP to be outputted as the current rising edge data DQP and controls the data rear section rising edge data multiplexer 130 to select the data rear section AND gate rising edge sampling result GAP to be outputted as the data rear section rising edge data DGP when the current rising edge sampling result is the low state.

FIG. 7 illustrates a table of the signal combinations for the rising edge selection circuit 140 to perform selection according to an embodiment of the present invention.

Contrary to FIG. 6, the first three rows in FIG. 7 illustrate three different timing conditions of the data sequence of (1, 0, 0) or (1, 0, 1). The data sequences are not illustrated herein.

As illustrate in the first row in FIG. 7, under the condition that the data middle timing TC is roughly aligned to the center of the data, the rising edge selection circuit 140 directly determines that the current rising edge sampling result is the low state when the previous falling edge sampling result SPN is the high state and the data front section rising edge data DLP is the low state.

As illustrate in the second row in FIG. 7, under the condition that the timing of the data is slightly leading such that the data middle timing TC is behind the center of the data, the rising edge selection circuit 140 determines that the current rising edge sampling result is the low state when the previous falling edge sampling result SPN is the high state, and each of the AND gate rising edge sampling result CAP and the OR gate rising edge sampling result COP is the low state.

As illustrate in the third row in FIG. 7, under the condition that the timing of the data is leading in a greater deal such that the data middle timing TC is way behind the center of the data, the rising edge selection circuit 140 determines that the current rising edge sampling result is the low state when each of the previous falling edge sampling result SPN, the data front section rising edge data DLP and the OR gate rising edge sampling result COP is the high state, the AND gate rising edge sampling result CAP is the low state and the rising edge phase state DPP is the lead state.

The entries in the first three rows in FIG. 7 are illustrated to be filled with mesh-like pattern to indicate the conditions that the current rising edge sampling result is determined to be the low state. As a result, the rising edge selection circuit 140 controls the rising edge data multiplexer 120 to select the AND gate rising edge sampling result CAP to be outputted as the current rising edge data DQP and controls the data rear section rising edge data multiplexer 130 to select the data rear section AND gate rising edge sampling result GAP to be outputted as the data rear section rising edge data DGP when the current rising edge sampling result is the low state.

The entries in the last two rows in FIG. 7 illustrate three different timing conditions of the data sequence of (1, 1, 0). The data sequence is not illustrated herein.

As illustrated in the fifth row in FIG. 7, under the condition that the data middle timing TC is roughly aligned to the center of the data or the timing of the data is slightly lagging such that the data middle timing TC is ahead of the center of the data, the rising edge selection circuit 140 determines that the current rising edge sampling result is the high state when the previous falling edge sampling result SPN is the high state, and each of the AND gate rising edge sampling result CAP and the OR gate rising edge sampling result COP is the high state.

As illustrate in the fourth row in FIG. 7, under the condition that the timing of the data is lagging in a greater deal such that the data middle timing TC is way ahead of the center of the data, the rising edge selection circuit 140 determines that the current rising edge sampling result is the low state when each of the previous falling edge sampling result SPN, the data front section rising edge data DLP and the OR gate rising edge sampling result COP is the high state, the AND gate rising edge sampling result CAP is the low state and the rising edge phase state DPP is the lag state.

It is appreciated that the sampling results corresponding to the conditions in the third row and the fourth row in FIG. 7 are quite close. As a result, the rising edge selection circuit 140 requires the aid of the rising edge phase state DPP to determine whether the data is the lead state or the lag state.

The entries in the last two rows in FIG. 7 are illustrated to be filled with dotted pattern to indicate the conditions that the current rising edge sampling result is determined to be the high state. As a result, when the current rising edge sampling result is the high state, the rising edge selection circuit 140 controls the rising edge data multiplexer 120 to select the OR gate rising edge sampling result COP to be outputted as the current rising edge data DQP and controls the data rear section rising edge data multiplexer 130 to select the data rear section OR gate rising edge sampling result GOP to be outputted as the data rear section rising edge data DGP.

The data phase state storage circuit 115 stores the data front section rising edge data DLP, the current rising edge data DQP and the data rear section rising edge data DGP to be the rising edge phase state DPP.

The rising edge phase state DPP is the lag state when each of the data front section rising edge data DLP and the current rising edge data DQP is the first state and the data rear section rising edge data DGP is the second state. For example, when each of the data front section rising edge data DLP and the current rising edge data DQP is the high state and the data rear section rising edge data DGP is the low state, or each of the data front section rising edge data DLP and the current rising edge data DQP is the low state and the data rear section rising edge data DGP is the high state, the rising edge phase state DPP indicates the lag state.

On the other hand, the rising edge phase state DPP is a lead state when the data front section rising edge data DLP is the first state and each of the current rising edge data DQP and the data rear section rising edge data DGP is the second state. For example, when the data front section rising edge data DLP is the high state and each of the current rising edge data DQP and the data rear section rising edge data DGP is the low state, or when the data front section rising edge data DLP is the low state and each of the current rising edge data DQP and the data rear section rising edge data DGP is the high state, the rising edge phase state DPP indicates the lead state.

The rising edge selection circuit 140 and the falling edge selection circuit 145 may, when the N+P-th data is being sampled, retrieve the rising edge phase state DPP stored corresponding to the sampling of the N-th data or an average of the rising edge phase state DPP stored corresponding to the sampling from the N−K-th data to the N-th data to determine whether the data is the lead state or the lag state accordingly, wherein each of P and K is an integer larger than or equal to 1.

By using the selection mechanism described above, the rising edge data multiplexer 120 and the data rear section rising edge data multiplexer 130 may select the OR gate rising edge sampling result COP and the data rear section OR gate rising edge sampling result GOP having a larger safe margin for the high state to be outputted as the current rising edge data DQP and the data rear section rising edge data DGP.

Further, the rising edge data multiplexer 120 and the data rear section rising edge data multiplexer 130 may select the AND gate rising edge sampling result CAP and the data rear section AND gate rising edge sampling result GAP having a larger safe margin for the low state to be outputted as the current rising edge data DQP and the data rear section rising edge data DGP.

As a result, besides the data sequences of (0, 0, 0) and (1, 1, 1) do not have the signal transition issue, the rising edge data multiplexer 120 and the data rear section rising edge data multiplexer 130 can accomplish the data valid window expanding mechanism for each of the combinations of the data sequence.

Similarly, the falling edge selection circuit 145 may determine the current falling edge sampling result according to previous rising edge sampling result SPP, the AND gate falling edge sampling result CAN, the OR gate falling edge sampling result CON and the falling edge phase state DPN and control the falling edge data multiplexer 125 and the data rear section falling edge data multiplexer 135 according to the current falling edge sampling result to perform the selection and the output of the signal. The previous rising edge sampling result SPP is neighboring to and ahead of the current falling edge sampling result.

More specifically, the falling edge selection circuit 145 controls the falling edge data multiplexer 125 to select the OR gate falling edge sampling result CON to be outputted as the current falling edge data DQN when the current falling edge sampling result is the high state, and controls the data rear section falling edge data multiplexer 135 to select the data rear section OR gate falling edge sampling result GON to be outputted as the data rear section falling edge data DGN.

On the other hand, the falling edge selection circuit 145 controls the falling edge data multiplexer 125 to select the AND gate falling edge sampling result CAN to be outputted as the current falling edge data DQN and controls the data rear section falling edge data multiplexer 135 to select the data rear section AND gate falling edge sampling result GAN to be outputted as the data rear section falling edge data DGN when the current falling edge sampling result is the low state.

The data phase state storage circuit 115 further stores the data front section falling edge data DLN, current falling edge data DQN and data rear section falling edge data DGN to be the falling edge phase state DPN.

Since the operation mechanism of the falling edge selection circuit 145 is the same as the operation mechanism of the rising edge selection circuit 140, the detail of the determination performed by the falling edge selection circuit 145 is not described herein.

The data receiving apparatus of the present invention performs an AND logic operation and an OR logic operation on an input data signal and a delayed data signal to generate an AND gate processed signal and an OR gate processed signal and perform sampling thereon. Further, according to previous sampling results and current sampling results, one of the AND gate sampling result and the OR gate sampling result having a larger secured margin is selected to be a current sampled data to accomplish the data valid window expanding mechanism. The accuracy of the data sampling is improved.

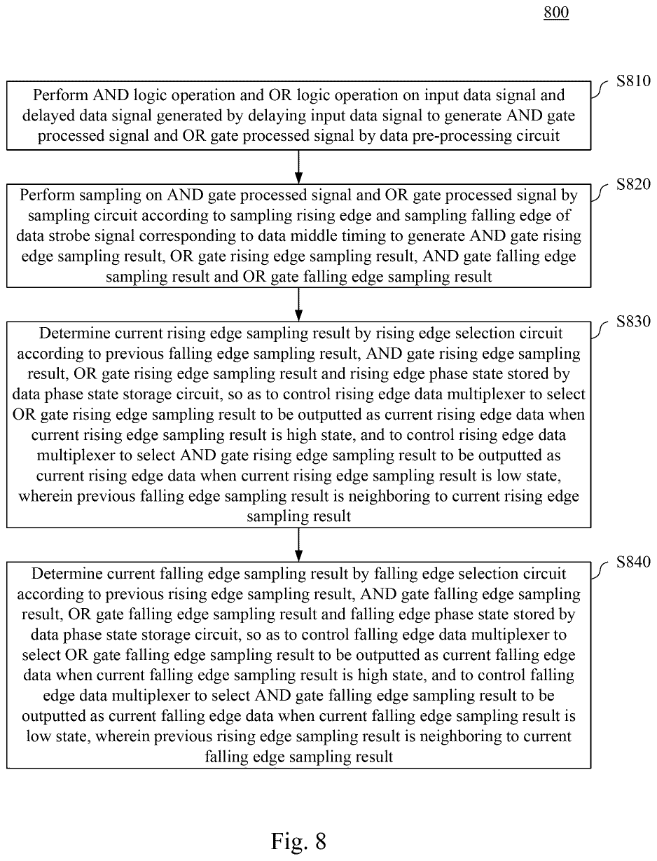

Reference is now made to FIG. 8. FIG. 8 illustrates a flow chart of a data receiving method 800 having a data valid window expanding mechanism according to an embodiment of the present invention.

In addition to the apparatus described above, the present disclosure further provides the data receiving method 800 having the data valid window expanding mechanism that can be used in such as, but not limited to, the data receiving apparatus 100 in FIG. 1. As illustrated in FIG. 8, an embodiment of the data receiving method 800 includes the following steps.

In step S810, the AND logic operation and the OR logic operation are performed on the input data signal DQ and the delayed data signal DDL generated by delaying the input data signal DQ to generate the AND gate processed signal DAN and the OR gate processed signal DOR by the data pre-processing circuit 105.

In step S820, sampling is performed on the AND gate processed signal DAN and the OR gate processed signal DOR by the sampling circuit 110 according to the sampling rising edge and the sampling falling edge of the data strobe signal DQS corresponding to the data middle timing to generate the AND gate rising edge sampling result CAP, the OR gate rising edge sampling result COP, the AND gate falling edge sampling result CAN and the OR gate falling edge sampling result CON.

In step S830, the current rising edge sampling result is determined by the rising edge selection circuit 140 according to the previous falling edge sampling result SPN, the AND gate rising edge sampling result CAP, the OR gate rising edge sampling result COP and the rising edge phase state DPP stored by the data phase state storage circuit 115, so as to control the rising edge data multiplexer 120 to select the OR gate rising edge sampling result COP to be outputted as the current rising edge data DQP when the current rising edge sampling result is the high state, and to control the rising edge data multiplexer 120 to select the AND gate rising edge sampling result CAP to be outputted as the current rising edge data DQP when the current rising edge sampling result is the low state, wherein the previous falling edge sampling result SPN is neighboring to the current rising edge sampling result.

In step S840, the current falling edge sampling result is determined by the falling edge selection circuit 145 according to the previous rising edge sampling result SPP, the AND gate falling edge sampling result CAN, the OR gate falling edge sampling result CON and the falling edge phase state DPN stored by the data phase state storage circuit 115, so as to control the falling edge data multiplexer 125 to select the OR gate falling edge sampling result CON to be outputted as the current falling edge data when the current falling edge sampling result is the high state, and to control the falling edge data multiplexer 125 to select the AND gate falling edge sampling result CAN to be outputted as the current falling edge data when the current falling edge sampling result is the low state, wherein the previous rising edge sampling result SPP is neighboring to the current falling edge sampling result.

It is appreciated that the embodiments described above are merely an example. In other embodiments, it should be appreciated that many modifications and changes may be made by those of ordinary skill in the art without departing, from the spirit of the disclosure.

In summary, the present invention discloses the data receiving apparatus and the data receiving method having the data valid window expanding mechanism to perform an AND logic operation and an OR logic operation on an input data signal and a delayed data signal to generate an AND gate processed signal and an OR gate processed signal and perform sampling thereon. Further, according to previous sampling results and current sampling results, one of the AND gate sampling result and the OR gate sampling result having a larger secured margin is selected to be a current sampled data to accomplish the data valid window expanding mechanism. The accuracy of the data sampling is improved.

The aforementioned descriptions represent merely the preferred embodiments of the present invention, without any intention to limit the scope of the present invention thereto. Various equivalent changes, alterations, or modifications based on the claims of present invention are all consequently viewed as being embraced by the scope of the present invention.

What is claimed is:

1. A data receiving apparatus having a data valid window expanding mechanism, comprising:
a data pre-processing circuit to perform an AND logic operation and an OR logic operation on an input data signal and a delayed data signal generated by delaying the input data signal to generate an AND gate processed signal and an OR gate processed signal;
a sampling circuit to perform sampling on the AND gate processed signal and the OR gate processed signal according to a sampling rising edge and a sampling falling edge of a data strobe signal corresponding to a data middle timing to generate an AND gate rising edge sampling result, an OR gate rising edge sampling result, an AND gate falling edge sampling result and an OR gate falling edge sampling result;
a data phase state storage circuit to store a rising edge phase state and a falling edge phase state;
a rising edge data multiplexer and a falling edge data multiplexer;
a rising edge selection circuit to determine a current rising edge sampling result according to a previous falling edge sampling result, the AND gate rising edge sampling result, the OR gate rising edge sampling result and the rising edge phase state, so as to control the rising edge data multiplexer to select the OR gate rising edge sampling result to be outputted as a current rising edge data when the current rising edge sampling result is a high state, and to control the rising edge data multiplexer to select the AND gate rising edge sampling result to be outputted as the current rising edge data when the current rising edge sampling result is a low state, wherein the previous falling edge sampling result is neighboring to the current rising edge sampling result; and
a falling edge selection circuit to determine a current falling edge sampling result according to the previous rising edge sampling result, the AND gate falling edge sampling result, the OR gate falling edge sampling result and the falling edge phase state, so as to control the falling edge data multiplexer to select the OR gate falling edge sampling result to be outputted as a current falling edge data when the current falling edge sampling result is the high state, and to control the falling edge data multiplexer to select the AND gate falling edge sampling result to be outputted as the current falling edge data when the current falling edge sampling result is the low state, wherein the previous rising edge sampling result is neighboring to the current falling edge sampling result.

2. The data receiving apparatus of claim 1, wherein the data pre-processing circuit comprises:
a data delay circuit to receive and delay the input data signal to generate the delayed data signal;
an AND gate to perform the AND logic operation on the input data signal and the delayed data signal to generate the AND gate processed signal; and
an OR gate to perform the OR logic operation on the input data signal and the delayed data signal to generate an OR gate processed signal.

3. The data receiving apparatus of claim 1, wherein the sampling circuit comprises:
a data middle section rising edge sampling circuit to, corresponding to the data middle timing, sample the AND gate processed signal according to the sampling rising edge of the data strobe signal to generate the AND gate rising edge sampling result and sample the OR gate processed signal according to the sampling rising edge of the data strobe signal to generate the OR gate rising edge sampling result; and
a data middle section falling edge sampling circuit to, corresponding to the data middle timing, sample the AND gate processed signal according to the sampling falling edge of the data strobe signal to generate the AND gate falling edge sampling result and sample he OR gate processed signal according to the sampling falling edge of the data strobe signal to generate the OR gate falling edge sampling result.

4. The data receiving apparatus of claim 3, wherein the sampling circuit further comprises:
a data front section rising edge sampling circuit to, corresponding to a data front section timing before the data middle timing, sample the input data signal according to the sampling rising edge of the data strobe signal to generate and output a data front section rising edge data;
a data front section falling edge sampling circuit to, corresponding to the data front section timing, sample the input data signal according to the sampling falling edge of the data strobe signal to generate and output a data front section falling edge data;
a data rear section rising edge sampling circuit to, corresponding to a data rear section timing behind the data middle timing, sample the AND gate processed signal according to the sampling rising edge of the data strobe signal to generate a data rear section AND gate rising edge sampling result and sample the OR gate processed signal according to the sampling rising edge of the data strobe signal to generate a data rear section OR gate rising edge sampling result; and
a data rear section falling edge sampling circuit to, corresponding to data rear section timing, sample the AND gate processed signal according to the sampling falling edge of the data strobe signal to generate a data rear section AND gate falling edge sampling result and sample the OR gate processed signal according to the sampling falling edge of the data strobe signal to generate a data rear section OR gate falling edge sampling result;
the data receiving apparatus further comprises a data rear section rising edge data multiplexer and a data rear section falling edge data multiplexer, wherein the rising edge selection circuit controls the data rear section rising edge data multiplexer to select the data rear section OR gate rising edge sampling result to be outputted as a data rear section rising edge data when the current rising edge sampling result is the high state, and controls the data rear section rising edge data multiplexer to select the data rear section AND gate rising edge sampling result to be outputted as the data rear section rising edge data when the current rising edge sampling result is the low state;
the falling edge selection circuit further controls the data rear section falling edge data multiplexer to select the data rear section OR gate falling edge sampling result to be outputted as a data rear section falling edge data when the current falling edge sampling result is the high state, and controls the data rear section falling edge data multiplexer to select the data rear section AND gate falling edge sampling result to be outputted as the data rear section falling edge data when the current falling edge sampling result is the low state; and
the data phase state storage circuit stores the data front section rising edge data, the current rising edge data and the data rear section rising edge data to be the rising edge phase state, and stores the data front section falling edge data, the current falling edge data and the data rear section falling edge data to be the falling edge phase state.

5. The data receiving apparatus of claim 4, wherein the rising edge phase state is a lag state when each of the data front section rising edge data and the current rising edge data is a first state and the data rear section rising edge data is a second state, and the rising edge phase state is a lead state when the data front section rising edge data is the first state and each of the current rising edge data and the data rear section rising edge data is the second state;
the falling edge phase state is the lag state when each of the data front section falling edge data and the current falling edge data is the first state and the data rear section falling edge data is the second state, and the falling edge phase state is the lead state when the data front section falling edge data is the first state and each of the current falling edge data and the data rear section falling edge data is the second state;
wherein the rising edge selection circuit determines that the current rising edge sampling result is the low state when each of the previous falling edge sampling result, the data front section rising edge data and the AND gate rising edge sampling result is the low state, the OR gate rising edge sampling result is the high state and the rising edge phase state is the lag state, and determines that the current rising edge sampling result is the high state when each the previous falling edge sampling result, the data front section rising edge data and the AND gate rising edge sampling result is the low state, the OR gate rising edge sampling result is the high state and the rising edge phase state is the lead state; and
the falling edge selection circuit determines that the current falling edge sampling result is the low state when each of the previous rising edge sampling result, the data front section falling edge data and the AND gate falling edge sampling result is the low state, the OR gate falling edge sampling result is the high state and the falling edge phase state is the lag state, and determines that the current falling edge sampling result is the high state when each of the previous rising edge sampling result, the data front section falling edge data and the AND gate falling edge sampling result is the low state, the OR gate falling edge sampling result is the high state and the falling edge phase state is the lead state.

6. The data receiving apparatus of claim 4, wherein the rising edge selection circuit directly determines that the current rising edge sampling result is the high state when the previous falling edge sampling result is the low state and the data front section rising edge data is the high state, and directly determines that the current rising edge sampling result is the low state when the previous falling edge sampling result is the high state and the data front section rising edge data is the low state; and
the falling edge selection circuit directly determines that the current falling edge sampling result is the high state when the previous rising edge sampling result is the low state and the data front section falling edge data is the high state, and directly determines that the current falling edge sampling result is the low state when the previous falling edge sampling result is the high state and the data front section falling edge data is the low state.

7. The data receiving apparatus of claim 4, wherein the rising edge selection circuit
determines that the current rising edge sampling result is the high state when each of the AND gate rising edge sampling result and the OR gate rising edge sampling result is the high state, and determines that the current rising edge sampling result is the low state when each of the AND gate rising edge sampling result and the OR gate rising edge sampling result is the low state; and
the falling edge selection circuit determines that the current falling edge sampling result is the high state when each of the AND gate falling edge sampling result and the OR gate falling edge sampling result is the high state, and determines that the current falling edge sampling result is the low state when each of the AND gate falling edge sampling result and the OR gate falling edge sampling result is the low state.

8. The data receiving apparatus of claim 1, further comprising:
a data strobe delay circuit to receive and delay an original data strobe signal corresponding to the input data signal to generate the data strobe signal.

9. A data receiving method having a data valid window expanding mechanism, comprising:
performing an AND logic operation and an OR logic operation on an input data signal and a delayed data signal generated by delaying the input data signal to generate an AND gate processed signal and an OR gate processed signal by a data pre-processing circuit;
performing sampling on the AND gate processed signal and the OR gate processed signal by a sampling circuit according to a sampling rising edge and a sampling falling edge of a data strobe signal corresponding to a data middle timing to generate an AND gate rising edge sampling result, an OR gate rising edge sampling result, an AND gate falling edge sampling result and an OR gate falling edge sampling result;
determining a current rising edge sampling result by a rising edge selection circuit according to a previous falling edge sampling result, the AND gate rising edge sampling result, the OR gate rising edge sampling result and a rising edge phase state stored by a data phase state storage circuit, so as to control a rising edge data multiplexer to select the OR gate rising edge sampling result to be outputted as a current rising edge data when the current rising edge sampling result is a high state, and to control the rising edge data multiplexer to select the AND gate rising edge sampling result to be outputted as the current rising edge data when the current rising edge sampling result is a low state, wherein the previous falling edge sampling result is neighboring to the current rising edge sampling result;
determining a current falling edge sampling result by a falling edge selection circuit according to the previous rising edge sampling result, the AND gate falling edge sampling result, the OR gate falling edge sampling result and a falling edge phase state stored by the data phase state storage circuit, so as to control a falling edge data multiplexer to select the OR gate falling edge sampling result to be outputted as a current falling edge data when the current falling edge sampling result is the high state, and to control the falling edge data multiplexer to select the AND gate falling edge sampling result to be outputted as the current falling edge data when the current falling edge sampling result is the low state, wherein the previous rising edge sampling result is neighboring to the current falling edge sampling result.

10. The data receiving method of claim 9, further comprising:
receiving and delaying the input data signal to generate the delayed data signal by a data delay circuit comprised by the data pre-processing circuit;
performing the AND logic operation on the input data signal and the delayed data signal to generate the AND gate processed signal by an AND gate comprised by the data pre-processing circuit; and
performing the OR logic operation on the input data signal and the delayed data signal to generate an OR gate processed signal by an OR gate comprised by the data pre-processing circuit.

11. The data receiving method of claim 9, further comprising:
corresponding to the data middle timing, sampling the AND gate processed signal according to the sampling rising edge of the data strobe signal to generate the AND gate rising edge sampling result and sampling the OR gate processed signal according to the sampling rising edge of the data strobe signal to generate the OR gate rising edge sampling result by a data middle section rising edge sampling circuit comprised by the sampling circuit; and
corresponding to the data middle timing, sampling the AND gate processed signal according to the sampling falling edge of the data strobe signal to generate the AND gate falling edge sampling result and sampling he OR gate processed signal according to the sampling falling edge of the data strobe signal to generate the OR gate falling edge sampling result by a data middle section falling edge sampling circuit comprised by the sampling circuit.

12. The data receiving method of claim 11, further comprising:
corresponding to a data front section timing before the data middle timing, sampling the input data signal according to the sampling rising edge of the data strobe signal to generate and output a data front section rising edge data by a data front section rising edge sampling circuit comprised by the sampling circuit;
corresponding to the data front section timing, sampling the input data signal according to the sampling falling edge of the data strobe signal to generate and output a data front section falling edge data by a data front section falling edge sampling circuit comprised by the sampling circuit;
corresponding to a data rear section timing behind the data middle timing, sampling the AND gate processed signal according to the sampling rising edge of the data strobe signal to generate a data rear section AND gate rising edge sampling result and sampling the OR gate processed signal according to the sampling rising edge of the data strobe signal to generate a data rear section OR gate rising edge sampling result by a data rear section rising edge sampling circuit comprised by the sampling circuit; and
corresponding to data rear section timing, sampling the AND gate processed signal according to the sampling falling edge of the data strobe signal to generate a data rear section AND gate falling edge sampling result and sampling the OR gate processed signal according to the sampling falling edge of the data strobe signal to generate a data rear section OR gate falling edge sampling result by a data rear section falling edge sampling circuit comprised by the sampling circuit;
the data receiving apparatus further comprises a data rear section rising edge data multiplexer and a data rear section falling edge data multiplexer, wherein
controlling a data rear section rising edge data multiplexer comprised by the data receiving apparatus by the rising edge selection circuit to select the data rear section OR gate rising edge sampling result to be outputted as a data rear section rising edge data when the current rising edge sampling result is the high state, and controls the data rear section rising edge data multiplexer to select the data rear section AND gate rising edge sampling result to be outputted as the data rear section rising edge data when the current rising edge sampling result is the low state;
controlling a data rear section falling edge data multiplexer comprised by the data receiving apparatus by the falling edge selection circuit to select the data rear section OR gate falling edge sampling result to be outputted as a data rear section falling edge data when the current falling edge sampling result is the high state, and controls the data rear section falling edge data multiplexer to select the data rear section AND gate falling edge sampling result to be outputted as the data rear section falling edge data when the current falling edge sampling result is the low state; and
storing the data front section rising edge data, the current rising edge data and the data rear section rising edge data to be the rising edge phase state, and stores the data front section falling edge data, the current falling edge data and the data rear section falling edge data to be the falling edge phase state by the data phase state storage circuit.

13. The data receiving method of claim 12, wherein the rising edge phase state is a lag state when each of the data front section rising edge data and the current rising edge data is a first state and the data rear section rising edge data is a second state, and the rising edge phase state is a lead state when the data front section rising edge data is the first state and each of the current rising edge data and the data rear section rising edge data is the second state, and the falling edge phase state is the lag state when each of the data front section falling edge data and the current falling edge data is the first state and the data rear section falling edge data is the second state, and the falling edge phase state is the lead state when the data front section falling edge data is the first state and each of the current falling edge data and the data rear section falling edge data is the second state, the data receiving method further comprises:
determining that the current rising edge sampling result is the low state by the rising edge selection circuit when each of the previous falling edge sampling result, the data front section rising edge data and the AND gate rising edge sampling result is the low state, the OR gate rising edge sampling result is the high state and the rising edge phase state is the lag state, and determining that the current rising edge sampling result is the high state by the rising edge selection circuit when each the previous falling edge sampling result, the data front section rising edge data and the AND gate rising edge sampling result is the low state, the OR gate rising edge sampling result is the high state and the rising edge phase state is the lead state; and
determining that the current falling edge sampling result is the low state by the falling edge selection circuit when each of the previous rising edge sampling result, the data front section falling edge data and the AND gate falling edge sampling result is the low state, the OR gate falling edge sampling result is the high state and the falling edge phase state is the lag state, and determining that the current falling edge sampling result is the high state by the falling edge selection circuit when each of the previous rising edge sampling result, the data front section falling edge data and the AND gate falling edge sampling result is the low state, the OR gate falling edge sampling result is the high state and the falling edge phase state is the lead state.

14. The data receiving method of claim 12, further comprising:
directly determining that the current rising edge sampling result is the high state by the rising edge selection circuit when the previous falling edge sampling result is the low state and the data front section rising edge data is the high state, and directly determining that the current rising edge sampling result is the low state by the rising edge selection circuit when the previous falling edge sampling result is the high state and the data front section rising edge data is the low state; and
directly determining that the current falling edge sampling result is the high state by the falling edge selection circuit when the previous rising edge sampling result is the low state and the data front section falling edge data is the high state, and directly determining that the current falling edge sampling result is the low state by the falling edge selection circuit when the previous falling edge sampling result is the high state and the data front section falling edge data is the low state.

15. The data receiving method of claim 12, further comprising:
determining that the current rising edge sampling result is the high state by the rising edge selection circuit when each of the AND gate rising edge sampling result and the OR gate rising edge sampling result is the high state, and determining that the current rising edge sampling result is the low state by the rising edge selection circuit when each of the AND gate rising edge sampling result and the OR gate rising edge sampling result is the low state; and
determining that the current falling edge sampling result is the high state by the falling edge selection circuit when each of the AND gate falling edge sampling result and the OR gate falling edge sampling result is the high state, and determining that the current falling edge sampling result is the low state by the falling edge selection circuit when each of the AND gate falling edge sampling result and the OR gate falling edge sampling result is the low state.

16. The data receiving method of claim 9, further comprising:
receiving and delaying an original data strobe signal corresponding to the input data signal to generate the data strobe signal by a data strobe delay circuit.
